(19) United States
(12) Patent Application Publication
(10) Pub. No.: US 2006/0250868 A1
(43) Pub. Date: Nov. 9, 2006

(54) Electronic component with improved precharging

(76) Inventors: Florian Schnabel, Hoehenkirchen (DE); Helmut Schneider, Munich (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/402,194

(22) Filed: Apr. 11, 2006

(30) Foreign Application Priority Data
Apr. 11, 2005 (DE) DE 102005016597.4

(51) Int. Cl. G11C 7/00

(52) U.S. Cl. 365/203

(57) ABSTRACT

An electronic component has a first bit line and a second bit line, which are coupled to a plurality of memory cells, a line for providing a precharging potential, a resistance component which is connected to the line, a first switch which is coupled between the resistance component and the first bit line for connection of the first bit line to the resistance component, and a second switch, which is coupled between the resistance component and the second bit line, for connection of the second bit line to the resistance component. The electrical resistance of the resistance component is controllable in order to assume a predetermined first resistance value or a predetermined second resistance value which is higher than the first resistance value.

### CROSS-REFERENCE TO RELATED APPLICATIONS

This application claims foreign priority benefits under 35 U.S.C. §119 to co-pending German patent application number DE 10 2005 016 597.4, filed Apr. 11, 2005. This related patent application is herein incorporated by reference in its entirety.

### BACKGROUND OF THE INVENTION

1. Field of the Invention

The present invention relates to an electronic component and to a method for operation of an electronic component, which improve the precharging process and reduce the power consumption of the component.

2. Description of the Related Art

In random access static or dynamic memory components (e.g., Static Random Access Memory or SRAM; Dynamic Random Access Memory or DRAM) and other memory modules, the memory cells are arranged at crossing points between bit lines and word lines. Each memory cell which is associated with the word line is connected to the bit line on which it is arranged by activation of a word line or by application of an appropriate signal to the word line.

The following text refers to a dynamic memory component as an example. Typically, in each case, two bit lines are connected to one read amplifier or sense amplifier. The read amplifier operates differentially and compares the potentials on the two bit lines which are connected to it. Activation of a word line results in one of the two bit lines being connected to a memory cell (active bit line). The other bit line, which is connected to the same read amplifier, is used as a reference bit line, to which no memory cell is generally connected.

Before the activation of a word line, all of the bit lines are set to a mid-potential Vbleq in a precharging or pre-charge process, with this mid-potential being between a high potential Vblh and a low potential Vbll.

After the activation of the word line, the connection of the active bit line to the memory cell which is associated with the crossing point between the active bit line and the word line results in a small potential difference, caused by the charge stored in the memory cell. This small potential difference is amplified by the read amplifier. In this case, one of the two bit lines assumes the high potential Vblh and the other assumes the low potential Vbll, depending on the charge or information that is stored in that memory cell. At the same time, this results in the charge that is stored in the memory cell being refreshed.

When the memory cell is disconnected from the active bit line again by deactivation of the word line, both bit lines are precharged again, and are set to the mid-potential Vbleq. In this case, the two bit lines which are connected to the read amplifier are short-circuited to one another by means of a switch. If the electrostatic capacitance of the two bit lines is approximately the same, this results in a potential approximately in the center between the high potential Vblh and the low potential Vbll, which corresponds to the mid-potential Vbleq. In order to compensate for small asymmetries, both bit lines are, furthermore, connected at the same time or subsequently via switches that are provided for this purpose to a Vbleq network, which provides the mid-potential Vbleq.

One frequent defect which occurs one or more times in each chip, statistically on average, is a short-circuit between a word line and a bit line at the crossing point itself. In the case of DRAMs, this short-circuit occurs particularly frequently at the selection transistor of a memory cell. Typically, to repair the defect, the word line involved is replaced by a redundant word line, and the bit line involved is likewise replaced by a redundant bit line. However, conventionally, no provision is made for individual driving of the switches in order to connect the bit lines to the Vbleq network during precharging. During precharging of the bit lines, the one bit line which is short-circuited to a word line is therefore also connected to the Vbleq network. Since the word line is at a potential other than the mid-potential Vbleq, the short-circuiting of the bit line to the word line loads the Vbleq network which can no longer accurately provide the mid-potential Vbleq.

In order to minimize the load on the Vbleq network and the discrepancy that results in between its potential and the mid-potential Vbleq, the switches for connection of the bit lines to the Vbleq network are designed to have as high an impedance as possible. In order to match the potentials on the bit lines to the mid-potential Vbleq as quickly as possible and as accurately as possible, the switches for connection of the bit lines to the Vbleq network must be designed to have as low an impedance as possible. A compromise must therefore be found between the two requirements. In this case, it is also necessary to take into account of the fact that the power consumption of the voltage source for production of the mid-potential Vbleq depends on the current terminated via the Vbleq network and to be provided by the voltage source. The lower the impedance of the bit lines which are connected to the Vbleq network, the higher, therefore, is the power consumption for provision of the mid-potential Vbleq.

### SUMMARY OF THE INVENTION

Embodiments of the present invention provide an electronic component and a method for operation of an electronic component, which allow rapid and good precharging of bit lines to the mid-potential while the mean power consumption is low.

Embodiments of the present invention are based on the idea of connecting bit lines for precharging via a controllable resistance component to the mid-potential Vbleq. The controllable resistance component may be a field-effect transistor or some other transistor.

When the electronic component or that sub-area of the electronic component in which the bit lines under consideration are located is in a rest state, these bit lines are connected to the mid-potential Vbleq via a high electrical resistance. In the rest state, no accesses take place for reading from or writing to memory cells which are associated with the bit lines. It is therefore possible to accept somewhat greater discrepancies in the potentials on the bit lines from the mid-potential Vbleq. The high-impedance connection ensures that, even in the event of a short-circuit between a word line and a bit line, the Vbleq network and the voltage source for production of the mid-potential Vbleq are loaded with only a small current.

When the electronic component or that subarea of the electronic component in which the bit lines under consideration are located is in an active state, these bit lines are connected to the mid-potential Vbleq via a low electrical resistance. In the active state, read or write access may be made at any time to a memory cell associated with the bit lines. The low-impedance connection of the bit lines to the mid-potential Vbleq ensures that there is a minimal discrepancy in the potentials on the bit lines from the mid-potential Vbleq.

One embodiment of the present invention thus matches the power consumption for precharging of the bit lines to the respective operating mode of the component, and to the requirements associated with it. In the rest mode, the power consumption for production of the mid-potential Vbleq is low, and in the active mode, there is only a small discrepancy between the potentials on the bit lines and the mid-potential Vbleq.

The power consumption of a conventional voltage source is dependent on the current drawn from it. A further reduction in the power consumption can be achieved according to one embodiment of the present invention by using a weaker voltage source for production of the mid-potential Vbleq in the rest mode than in the active mode.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic circuit diagram of an electronic component according to one embodiment of the invention; and

FIG. 2 shows a schematic flowchart of a method for operation of an electronic component.

### DETAILED DESCRIPTION OF THE PREFERRED EMBODIMENT

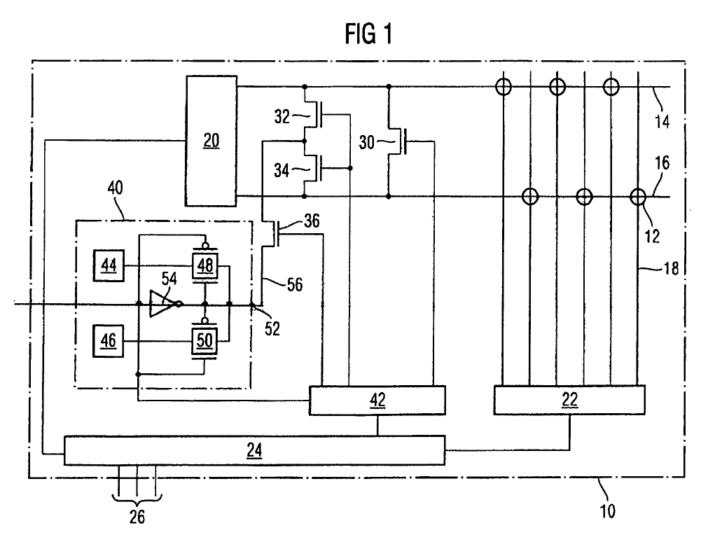

FIG. 1 shows a schematic circuit diagram of an electronic component 10. This component 10 is, for example, a memory component, in particular a DRAM or an SRAM. Alternatively, the electronic component 10 may be any desired component with a plurality of memory cells, for example, a processor with a cache memory.

The component 10 has a plurality of memory cells 12, which are represented schematically by circles in FIG. 1. Each memory cell 12 is arranged at a crossing of a bit line 14, 16 with a word line 18. In the case of a DRAM, each memory cell 12 has a selection transistor and a storage capacitor. The selection transistor connects the storage capacitor to the respective bit line 14, 16, controlled by the respective word line 18.

One pair of bit lines 14, 16 is in each case connected to one differential read amplifier (sense amplifier), by means of which information can be written to the memory cells 12 and read from them. FIG. 1 shows only a single read amplifier 20 and two bit lines 14, 16. However, the component 10 may have any desired number of read amplifiers 20 and bit lines 14, 16.

The word lines 18 are connected to a line decoder 22 which, as a function of a received line address, activates a word line that is identified by that line address. A controller 24 is connected via control, address and data lines 26 to a circuit outside the component 10, in order to receive control, address and data signals from the outside circuit, and to send the signals to the outside circuit. Furthermore, the controller 24 in the present example may include a column address decoder for selection of a read amplifier 20 which is identified by a column address.

A short-circuiting switch 30 is connected between the bit lines 14, 16. A first precharging switch 32 and a second precharging switch 34 are connected between the first bit line 14 and the second bit line 16 on one end, respectively, and a controllable resistance component 36 on the other end. The controllable resistance component 36 is connected between the precharging switches 32, 34 and a voltage source 40 for production of a mid-potential Vbleq. The short-circuiting switch 30, the precharging switches 32, 34 and the controllable resistance component 36 may comprise field-effect transistors. Alternatively, the short-circuiting switch 30 and/or the precharging switches 32, 34 may comprise bipolar transistors or other semiconductor switches. The controllable resistance component 36 can also alternatively comprise a bipolar transistor or any other desired component with a controllable electrical resistance.

A precharging controller 42 is operatively coupled to the short-circuiting switch 30, to the precharging switches 32, 34 and to the controllable resistance component 36, in order to control them.

When the controller 24 receives, via the control, address and data lines 26, a control signal which indicates a writing process, an address signal which represents an address of a memory cell and a data item which is to be written to the memory cell identified by the address signal, the line address decoder 22 activates the word line 18 associated with the identified memory cell 12. At the same time, the controller 24 selects the read amplifier 20 associated with the memory cell 12, and the read amplifier 20 writes the data item to the memory cell which is connected to the read amplifier 20 by the activated word line 18, via one of the bit lines 14, 16.

When the controller 24 receives a control signal which indicates a reading process, and an address signal which identifies a memory cell 12 from which a data item is intended to be read, the line address decoder 22 activates the word line 18 associated with the identified memory cell 12. The read amplifier 20 reads the data item which is stored in the memory cell that is connected to the selected read amplifier 20 by the activated word line 18, via one of the bit lines 14, 16. This data item is emitted via the controller 24 and the control, address and data lines 26 to the outside circuit connected to the component 10.

For each writing and reading process by the read amplifier 20, one of the bit lines 14, 16 which is connected to the read amplifier 20 assumes a high potential Vblh, and the other of the two bit lines 14, 16 which is connected to the read amplifier 20 assumes a low potential Vbll as a function of the data item being written or read. After completion of the writing or reading process and deselection of the word line 18, both bit lines 14, 16 are set to a mid-potential Vbleq in preparation for a subsequent access to a memory cell which is connected to one of the two bit lines 14, 16. The mid-potential Vbleq is between the high potential Vblh and the low potential Vbll, with the potential difference between the high potential Vblh and the mid-potential Vbleq, and the potential difference between the mid-potential Vbleq and the low potential Vbll, being about the same.

For this purpose, the short-circuiting switch 30 is first of all closed, controlled by the precharging controller 42, in order to short-circuit the bit lines 14, 16. As a result of this short-circuit, the bit lines 14, 16 are at the same potential, although this may not be the same as the mid-potential Vbleq, for example because of the bit lines 14, 16 having different electrostatic capacitances. In order to decrease this difference and to apply the mid-potential Vbleq as accurately as possible to both bit lines 14, 16, the two precharging switches 32, 34 are closed, controlled by the precharging controller 42, at the same time as or shortly after the closing of the short-circuiting switch 30. The bit lines 14, 16 are thus connected via the controllable resistance component 36 to the voltage source 40, and assume the mid-potential Vbleq. The short-circuiting switches 30 and the precharging switches 32, 34 are opened at the latest at the start of a write access or read access, immediately before a memory cell is connected to one of the bit lines 14, 16 by activation of a word line.

The controller 24 receives, via the control, address and data lines 26, a signal which controls the operating mode of the component 10. Alternatively, the controller 24 itself controls the operating mode of the component 10, on the basis of the received control, address and data signals. According to one alternative, the controller 24 controls the operating mode for individual read amplifiers or groups of read amplifiers and bit lines 14, 16 that are connected to them, or for larger memory areas.

In a rest mode, no accesses take place to memory cells 12. Before access to a memory cell 12, the corresponding read amplifier 20 and the corresponding bit lines 14, 16 and/or the corresponding memory areas must be set to an active mode. In the active mode, write access or read access to the memory cells 12 may be performed at any time.

In the active mode, the precharging controller 42 controls the controllable resistance component 36 such that it has a first, low resistance value. Any increase in the power consumption of the power source 40 that results from this is accepted in order to achieve a minimal potential difference in the active mode between the bit lines 14, 16 and the mid-potential Vbleq, and thus a minimal sense margin and maximum sensitivity of the read amplifier 20.

In the rest mode, the precharging controller 42 controls the controllable resistance component 36 such that it has a second, high resistance. The somewhat greater discrepancies that result from this between the bit lines 14, 16 and the mid-potential Vbleq are accepted in order to reduce the current to be produced by the voltage source 40, and thus the power consumption of the voltage source 40.

FIG. 1 shows the controllable resistance component 36 as a field-effect transistor. In the active mode, the first, low resistance value is produced by the precharging controller 42 applying a voltage to the gate electrode of the field-effect transistor 36 which is above, or well above, its threshold voltage Vₜ. In the rest mode, the precharging controller 42 applies a lower voltage to the gate electrode of the field-effect transistor 36, with this lower voltage being below the threshold voltage Vₜ.

By way of example, it is also possible to use a bipolar transistor instead of a field-effect transistor, or any other desired component whose resistance can controllably assume at least two different values. However, it is also possible to use a circuit comprising one or two series-connected resistance components each having a constant resistance, at least one of which can be bridged or short-circuited by a bypass switch, or a parallel circuit formed by resistance components, with at least one switch being arranged in series with one of the parallel-connected resistance components, or else further, more complex circuits. The resistances or resistance values of the controllable resistance component 36 in the active mode and in the rest mode may differ by a factor of 3 to 5, or alternatively by a greater or lesser factor.

As has already been explained above, conventional voltage sources have a power consumption which depends on the current drawn. The high resistance of the controllable resistance component 36 in the rest mode and the small current drawn from the voltage source 40 that this results in mean that the power consumption of the voltage source 40 is low in the rest mode.

A further improvement can be achieved by forming the voltage source 40 from two voltage source elements 44, 46, which can be connected via switches 48, 50 to the output 52 of the voltage source. The precharging controller 42 controls the switches 48, 50 such that, in the active mode a first, stronger voltage source element with a higher power consumption produces the mid-potential Vbleq at the output 52 of the voltage source 40 while, in the rest mode, a second, weaker source voltage element 46 produces the mid-potential Vbleq at the output 52 of the voltage source 40. This makes it possible to achieve a further optimization of the power consumption of the voltage source 40, in particular when the power supply for the voltage source elements 44, 46 is switchable at the same time.

In this case, the switches 48, 50 may be in the form of transmission gates, with each transmission gate comprising a parallel circuit formed by an n-channel field-effect transistor and a p-channel field-effect transistor. The gate electrodes of the p-channel field-effect transistor of the first transmission gate 48 and of the n-channel field-effect transistor of the second transmission gate 50 are driven directly by the precharging controller 42, and the gate electrodes of the n-channel field-effect transistor of the first transmission gate 48 and of the p-channel field-effect transistor of the second transmission gate 50 are driven via an inverter 54 by the precharging controller 42. One of the two transmission gates 48, 50 is always open, and the other is always closed, by a logic signal from the precharging controller 42.

Alternatively, in the rest mode, one voltage source element or a first, smaller number of parallel-connected voltage source elements is or are operated, while, in the active mode, two parallel-connected voltage source elements or a second, greater number of parallel-connected voltage source elements is or are operated. The voltage source 40 thus has a low-impedance state with a first, low output resistance, and a high-impedance state with a second, high output resistance. In the active mode, the precharging controller 42 switches the voltage source 40 to the low-impedance state, and in the rest mode the precharging controller 42 switches the voltage source 40 to the high-impedance state.

In the case of a voltage source 40 formed from a plurality of switchable voltage source elements 44, 46, one voltage source 40 may be provided in each read amplifier 20 or for each group of read amplifiers 20 and bit lines 14, 16 which are always in the same operating mode at the same time. When the entire component 10 or at least all of the bit lines 14, 16 and read amplifiers 20 of the component 10 are always in the same operating mode at the same time, and/or when the voltage source 40 cannot be switched other than as illustrated in FIG. 1 and, in particular, is not formed from voltage source elements 44, 46, only a single voltage source 40 may be provided for the entire component 10. The line 56 between the output 52 of the voltage source 40 and the controllable resistance component 36 is in this case a potential rail, which is connected from each bit line pair 14, 16 to the controllable resistance components 36.

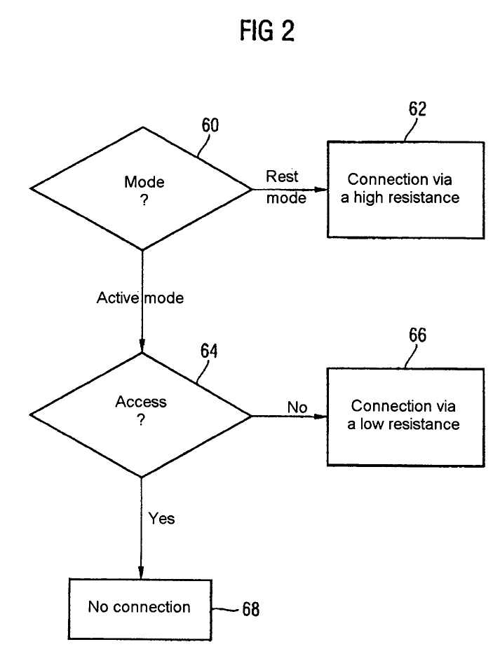

FIG. 2 shows a schematic flowchart which illustrates a method such as that which takes place in the electronic component 10 described above with reference to FIG. 1 and which, in particular, is controlled by the precharging controller 42.

In a first step 60, a check is carried out to determine whether the electronic component 10 or a part of it is in the rest mode or in the active mode. When the component 10 or the part of it is in the rest mode, the bit lines 14, 16 are connected via a high resistance to the mid-potential Vbleq in a second step 62. As described above, the high resistance is in this case provided by the controllable resistance component 36 in a high-impedance state.

When the electronic component 10 or the part of it is in the active mode, a check is carried out in a third step 64 to determine whether a read access or write access to one of the memory cells 12 which is connected to the first or to the second bit lines 14, 16 is taking place, or is immediately imminent. If this is not the case, the bit lines 14, 16 are connected to the mid-potential Vbleq via a low resistance in a fourth step 66. The low resistance may be provided, as described above, by the controllable resistance component 36 in a low impedance state. When the electronic component 10 or the part of it that is in the active mode, and an access is taking place to a memory cell 12 which is connected to the first or to the second bit line 14, 16, or such an access is immediately imminent, the bit lines 14, 16 are not connected to the mid-potential Vbleq.

While the foregoing is directed to embodiments of the present invention, other and further embodiments of the invention may be devised without departing from the basic scope thereof, and the scope thereof is determined by the claims that follow.

What is claimed is:

1. An electronic component, comprising:
a plurality of memory cells;
a first bit line and a second bit line which are coupled to the plurality of memory cells;
a line for providing a precharging potential;
a resistance component connected to the line, wherein an electrical resistance of the resistance component is controllable to selectively assume one of at least a predetermined first resistance value and a predetermined second resistance value which is greater than the first resistance value;
a first switch coupled between the resistance component and the first bit line to selectively connect the first bit line to the resistance component; and
a second switch coupled between the resistance component and the second bit line to selectively connect the second bit line to the resistance component.

2. The electronic component of claim 1, wherein the resistance component is a transistor.

3. The electronic component of claim 1, wherein the resistance component is a field-effect transistor.

4. The electronic component of claim 1, further comprising:
a differential read amplifier whose input is connected to the first and to the second bit line and which applies a predetermined low potential to one of the first and second bit lines and a predetermined high potential to the other of the first and second bit lines, for each writing process and for each reading process,
wherein the precharging potential is between the predetermined low potential and the predetermined high potential, and wherein a difference between the predetermined high potential and the precharging potential is about the same as a difference between the precharging potential and the predetermined low potential.

5. The electronic component of claim 1, further comprising:
a precharging controller, which is operatively connected to control the first switch, the second switch and the resistance component.

6. The electronic component of claim 5, wherein the precharging controller is configured to:
open the first and the second switch while writing to and while reading from a memory cell which is connected to one of the first and the second bit line;
close the first and the second switches during an active mode and control the resistance component to provide the predetermined first resistance value; and
close the first and the second switch during a rest mode and control the resistance component to provide the predetermined second resistance value.

7. The electronic component of claim 6, wherein, in the rest mode, the memory cells which are connected to one of the first and second bit lines are neither written to nor read from, and wherein, before writing to and before reading from a memory cell which is connected to the first and second bit lines, the electronic component is switched to the active mode.

8. The electronic component of claim 1, further comprising:
a voltage source, connected to the line, for providing the precharging potential, wherein the voltage source selectively provides a first output resistance and a first power consumption in a low-impedance state, and a second output resistance, which is higher than the first output resistance, and a second power consumption, which is lower than the first power consumption, in a high-impedance state.

9. A method for operating an electronic component having a plurality of memory cells coupled to a first bit line and a second bit line, comprising:
determining whether the electronic component is in one of a rest mode and an active mode;
determining whether one of the memory cells which are connected to one of the first and second bit lines is being written to or read from;
connecting the first bit line and the second bit line to a precharging potential via a first resistance when the electronic component is in the active mode and when none of the memory cells which are connected to one of the first and second bit lines is being written to or read from; and
connecting the first bit line and the second bit line to the precharging potential via a second resistance when the electronic component is in the rest mode, wherein the second resistance is higher than the first resistance.

10. The method of claim 9, further comprising:
disconnecting the first bit line and the second bit line to the precharging potential prior to and during an access to one of the memory cells connected to one of the first and second bit lines.

11. The method of claim 9, further comprising:
connecting a voltage source for providing the precharging potential to the first and second bit lines, wherein the voltage source selectively provides a first output resistance and a first power consumption in a low-impedance state during the active mode.

12. The method of claim 11, wherein the voltage source selectively provides a second output resistance, which is higher than the first output resistance, and a second power consumption, which is lower than the first power consumption, in a high-impedance state during the rest mode.

13. An apparatus, comprising:
a plurality of memory cells;
a first bit line and a second bit line which are coupled to the plurality of memory cells;
a line for providing a precharging potential to the first and second bit lines; and
a resistance component connected in series to the line, wherein an electrical resistance of the resistance component is selectable between at least a first resistance and a second resistance which is greater than the first resistance.

14. The apparatus of claim 13, wherein the resistance component is selected with the first resistance in an active mode during a time period before an access to the memory cells.

15. The apparatus of claim 14, wherein the resistance component is selected with the second resistance in a rest mode.

16. The apparatus of claim 15, further comprising:
a voltage source, connected to the line, for providing the precharging potential, wherein the voltage source selectively provides a first output resistance and a first power consumption in a low-impedance state during the active mode, and a second output resistance, which is higher than the first output resistance, and a second power consumption, which is lower than the first power consumption, in a high-impedance state during the rest mode.

17. The apparatus of claim 16, further comprising:
a first switch coupled between the resistance component and the first bit line to selectively connect the first bit line to the resistance component; and
a second switch coupled between the resistance component and the second bit line to selectively connect the second bit line to the resistance component.

18. The apparatus of claim 17, further comprising:
a precharging controller, which is operatively connected to control the first switch, the second switch, the resistance component and the voltage source.

19. The apparatus of claim 18, wherein the voltage source comprises a plurality of voltage source elements and a plurality of switches which are selectively controlled by the precharging controller to provide a high power consumption during the active mode and low power consumption during the rest mode.

20. The apparatus of claim 13, wherein the second resistance is between three and five times higher than the first resistance.
